(19) United States
(12) Patent Application Publication
(10) Pub. No.: US 2016/0025776 A1
(43) Pub. Date: Jan. 28, 2016

(54) PROBES AND PROBE ASSEMBLIES FOR WAFER PROBING

(71) Applicant: QUALCOMM Incorporated, San Diego, CA (US)

(72) Inventors: Young Kyu SONG, San Diego, CA (US); Chang-Ho LEE, San Diego, CA (US)

(21) Appl. No.: 14/340,387

(22) Filed: Jul. 24, 2014

(51) Int. Cl. G01R 1/067; G01R 31/28; G01R 1/073

(52) U.S. Cl. CPC G01R 1/06722; G01R 1/073; G01R 31/2851

(57) ABSTRACT

In one aspect, a probe assembly for probing an IC is provided. The probe assembly includes a probe, which includes a probe head for contacting the integrated circuit and a body. The probe head is elongated in a first direction. The body includes a spring and an edge portion contacting the probe head. One conductor extends in a second direction and is configured to connect to a voltage potential. An electric field between the probe and the at least one conductor is perpendicular to a magnetic field of the probe. In another aspect, a probe assembly includes a first probe and second probe. Each of the first probe and the second probe is elongated in a first direction and is configured to contact an IC. A conductor extends in a second direction is provided between the first probe and the second probe. The conductor is connected to a voltage potential.

### BACKGROUND

1. Field

The present disclosure relates generally to electronic apparatus, and more particularly, to probes and probe assemblies for wafer probing.

2. Background

A probe assembly, such as a probe card having a plurality of probes attached thereon, is mainly utilized in wafer probing. The probes contact the wafer (e.g., the integrated circuits thereon), usually in a vertical direction. The probes may supply powers or measure signals on the integrated circuits. The wafer probing screens out defective dies, which can be fixed or discarded. Consequently, the subsequent packaging can be carried out on the good dies, and the yield of the packaged products may be improved.

The wafer probing processing may be applied to wireless devices and the radio frequency (RF) pins thereof. The probing of RF signals may measure the signals for RF specifications such as gain, isolation, harmonic, linearity, and noise. Along with the miniaturization of the critical dimension of integrated circuits, different types of probes having been developed to meet the new demands. The probes may include a spring-probe type which includes a body portion having a spring for supplying a contact force from the probe head to wafer surface. A membrane probe includes a membrane spanned over a plunger on one surface and having contacting bumps on another surface. The plunger supplies the contacting force to the bumps and the wafer surface.

### SUMMARY

Aspects of a probe assembly for probing an integrated circuit are provided. The probe assembly includes a probe, which includes a probe head for contacting the integrated circuit and a body. The probe is elongated in a first direction. The body including a spring and an edge portion contacting the probe head. At least one conductor extends in a second direction and is configured to connect to a voltage potential. An electric field between the probe and the at least one conductor is perpendicular to a magnetic field of the probe.

Aspects of a probe assembly for probing an integrated circuit are provided. The probe assembly includes a first probe and second probe. Each of the first probe and the second probe is elongated in a first direction and is configured to contact an IC. At least one conductor extends in a second direction between the first probe and the second probe. The least one conductor is connected to a voltage potential.

Aspects of a method for operating a probe assembly for probing an integrated circuit are provided. The method includes measuring the integrated circuit via a probe, which includes a probe head for contacting the integrated circuit and a body. The probe is elongated in a first direction. The body includes a spring and an edge portion contacting the probe head. The method further includes providing a voltage potential to at least one conductor extending in a second direction. An electric field between the probe and the at least one conductor is perpendicular to a magnetic field of the probe.

It is understood that other aspects of apparatus, circuits and methods will become readily apparent to those skilled in the art from the following detailed description, wherein various aspects of apparatus, circuits and methods are shown and described by way of illustration. As will be realized, these aspects may be implemented in other and different forms and its several details are capable of modification in various other respects. Accordingly, the drawings and detailed description are to be regarded as illustrative in nature and not as restrictive.

### BRIEF DESCRIPTION OF THE DRAWINGS

Various aspects of apparatus, circuits and methods will now be presented in the detailed description by way of example, and not by way of limitation, with reference to the accompanying drawings, wherein:

FIG. 1 is a diagram illustrating an exemplary embodiment of a spring probe.

FIG. 2 is a diagram of an isometric view of an exemplary embodiment of a probe assembly.

FIG. 3A is a diagram of a top view of an exemplary embodiment of a probe assembly.

FIG. 3B is a diagram of a side view of an exemplary embodiment of a probe assembly.

FIG. 4A is a diagram illustrating the electric and magnetic fields of a spring probe and the conductors.

FIG. 4B is a diagram illustrating the equivalent circuit of the probes and conductors.

FIG. 5 is a diagram of a top view of another exemplary embodiment of a probe assembly.

FIG. 6 is a diagram of a side view of another exemplary embodiment of a probe assembly.

FIG. 7 is a flow chart for operating an exemplary embodiment of a probe assembly.

### DETAILED DESCRIPTION

The detailed description set forth below in connection with the appended drawings is intended as a description of various exemplary embodiments of the present invention and is not intended to represent the only embodiments in which the present invention may be practiced. The detailed description includes specific details for the purpose of providing a thorough understanding of the present invention. However, it will be apparent to those skilled in the art that the present invention may be practiced without these specific details. In some instances, well-known structures and components are shown in block diagram form in order to avoid obscuring the concepts of the present invention. Acronyms and other descriptive terminology may be used merely for convenience and clarity and are not intended to limit the scope of the invention.

The word “exemplary” is used herein to mean serving as an example, instance, or illustration. Any embodiment described herein as “exemplary” is not necessarily to be construed as preferred or advantageous over other embodiments. Likewise, the term “embodiment” of an apparatus, circuit or method does not require that all embodiments of the invention include the described components, structure, features, functionality, processes, advantages, benefits, or modes of operation.

The terms “connected,” “coupled,” or any variant thereof, mean any connection or coupling, either direct or indirect, between two or more elements, and can encompass the presence of one or more intermediate elements between two elements that are “connected” or “coupled” together. The coupling or connection between the elements can be physical, logical, or a combination thereof. As used herein, two elements can be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

Any reference to an element herein using a designation such as “first,” “second,” and so forth does not generally limit the quantity or order of those elements. Rather, these designations are used herein as a convenient method of distinguishing between two or more elements or instances of an element. Thus, a reference to first and second elements does not mean that only two elements can be employed, or that the first element must precede the second element.

As used herein, the terms “comprises”, “comprising,”, “includes” and/or “including”, when used herein, specify the presence of the stated features, integers, steps, operations, elements, and/or components, but do not preclude the presence or addition of one or more other features, integers, steps, operations, elements, components, and/or groups thereof.

In one example, the spring probe inductance is higher than a membrane probe inductance. In one example, the spring probe inductance may reach 0.9 nH. A membrane probe inductance may be as low as 0.2 nH. The higher inductance of the spring probe may distort the result when probing an RF signal (e.g., the power amplifier of a wireless transmitter). However, the contact resistance of a membrane probe is higher than that of the spring probe, and the direct current (DC) capacity of the membrane probe is lower than that of the spring probe. As a result, using a membrane probe may take longer (and therefore more costly) than using the spring probe.

Various embodiments of a probe and a probe assembly for wafer probing are presented. In one implementation, the probes are the spring-probe type for probing RF signals. In one implementation, conductors are provided near the probes to reduce the effects of the probe inductances. However, as those skilled in the art will readily appreciate, such aspects may be extended to other circuit configurations and devices. For example, the present disclosure may include wafer probes of types other than the spring-probe type.

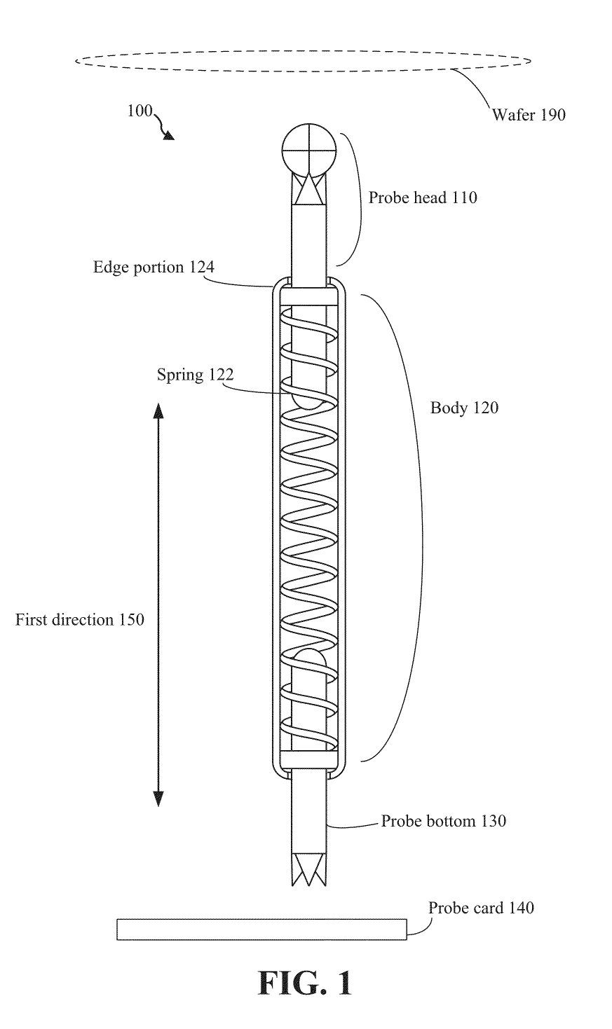

FIG. 1 is a diagram of an exemplary embodiment of a spring probe. The spring probe 100 includes a probe head 110, a body 120, and a probe bottom 130. The spring probe 100 is elongated in a first direction 150. The probe head 110 is configured to travel in the first direction 150 (e.g., alone the elongated direction) for contacting the integrated circuit on the wafer 190. The body 120 including a spring 122 and an edge portion 124, which contacts the probe head 110. When the probe head 110 contacts the integrated circuit, the spring 122 compresses and provides the contacting force to the probe head 110 and the integrated circuit. The probe bottom 130 may be attached to a probe card 140, which may be connected to a tester for measuring signals on the probe head 110 or providing a voltage to the probe 100.

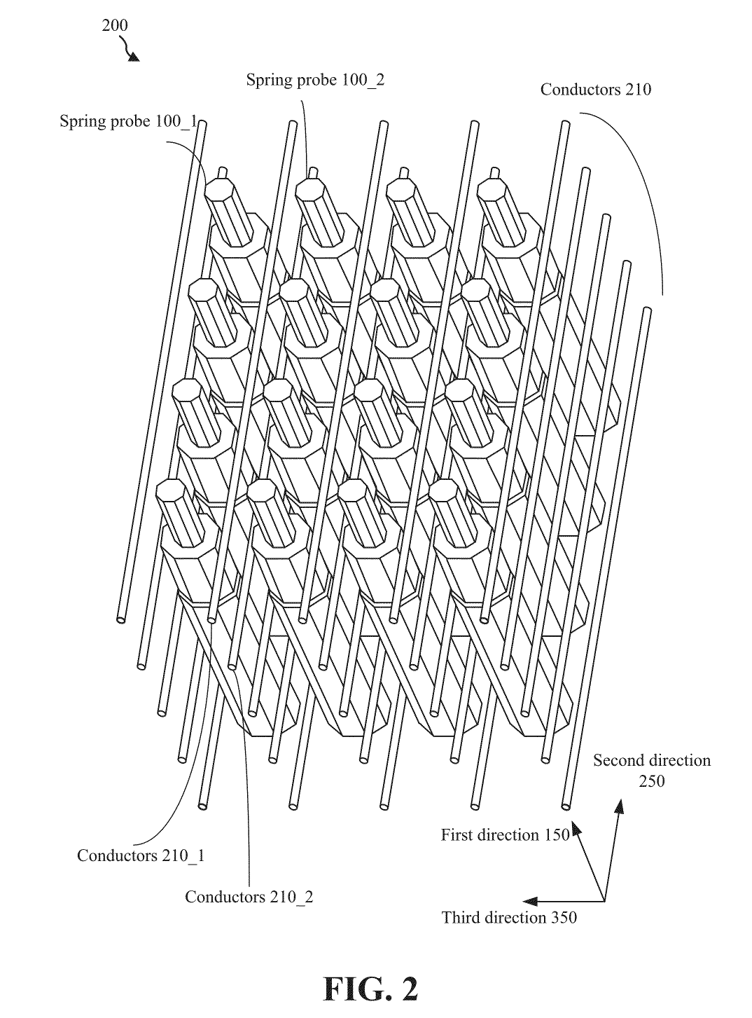

FIG. 2 is a diagram of an isometric view of an exemplary embodiment of a probe assembly. An example of a probe assembly may include a probe card having probes attached thereon. The probe card may be configured to connect to a test resource, such as a tester, for measuring the signals received on the probes and/or providing signals to the probes for delivering the signals to an integrated circuit. The probe assembly 200 includes a plurality of probes, such as spring probes 100_1 and 100_2, arranged in a 4×4 array and configured for contacting the integrated circuit on a wafer. The conductors 210 include the conductor 210_1 extending in a second direction 250. In one example, the first direction 150 and the second direction 250 are orthogonal. In one implementation, the conductor 210_1 includes a metal wire and is connected to a voltage potential, such as ground. The conductors 210 may further include the conductor 210_2 extending in a second direction 250. The conductor 210_2 may include a metal wire and is connected to a voltage potential, such as ground.

In one implementation, the conductors are placed in proximity to the probe heads of the spring probes. For example, the conductor 210_1 may be aligned with the edge portion 124 of the spring probe 100_1. Further, the probe head 110 is configured to travel in the first direction 150 as the spring probe 100_1 contacts the integrated circuit and depresses the spring 122. In one implementation, the conductor 210_1 is disposed or aligned beyond the body 120 and the edge portion 124, such that the probe head 110 is allowed to travel and contact the integrated circuit for probing.

In one implementation, the spring probe 100_1 and the spring probe 100_2 are each elongated in a first direction 150 and configured to contact an integrated circuit on the wafer 190. The conductor 210_1 extends in a second direction 250 between the spring probe 100_1 and the spring probe 100_2. The conductor 210_1 is connected to a voltage potential, such as ground. The conductor 210_2 also passes through between the spring probe 100_1 and the spring probe 100_2, and the conductor 210_1 and the conductor 210_2 are parallel in the first direction 150.

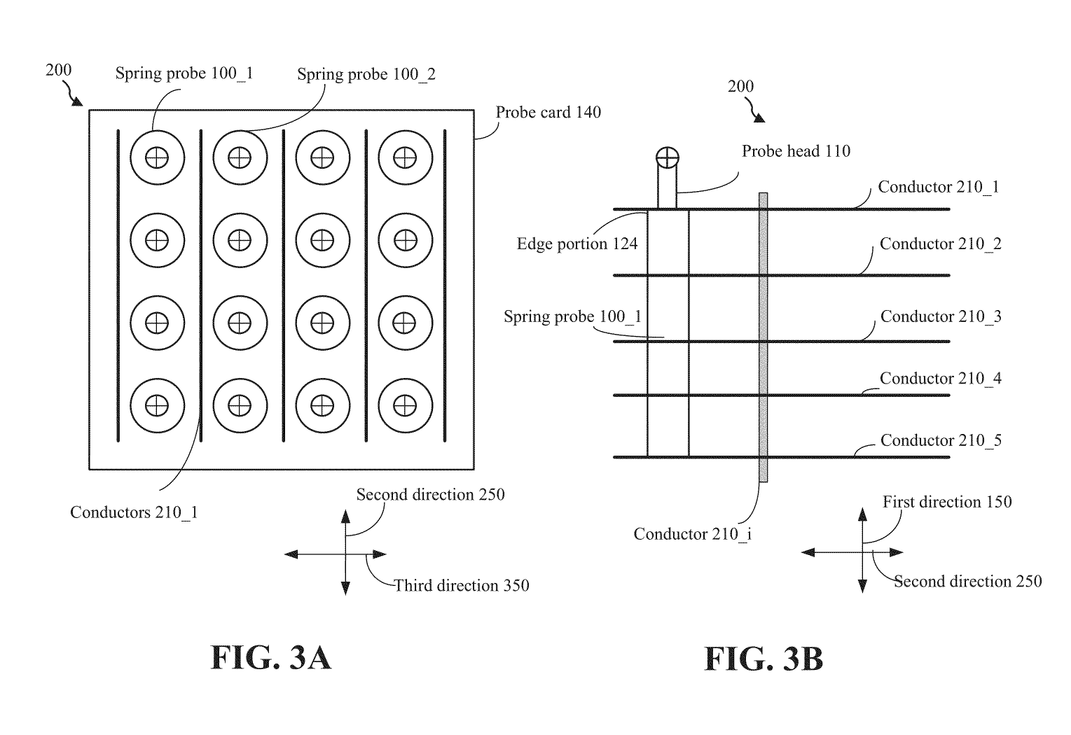

FIG. 3A is a diagram of a top view of an exemplary embodiment of a probe assembly. In the diagram, the first direction 150 would be coming out of the page. The probe assembly 200 includes spring probes (include spring probes 100_1 and 100_2) arranged as a 4×4 array in the second direction 250 and the third direction 350. In one implementation, the third direction 350 is orthogonal to both the first direction 150 and the second direction 250. The spring probes are attached to a probe card 140. Conductors (including the conductor 210_1) extend along the second direction 250. FIG. 3B is a diagram of a side view of an exemplary embodiment of a probe assembly. In this view, the third direction 350 would be coming out of the page. Only spring probe 100_1 is shown for clarity. The conductors 210_1, 210_2, 210_3, 210_4, and 210_5 extend in the second direction 250 and are parallel in the first direction 150. The conductor 210_1 is generally aligned with the edge portion 124 of the spring probe 100_1. Optionally, the conductors 210 may include a conductor 210_i extending in the first direction 150. The conductor 210_i may include a metal wire, and may connect to the conductors 210. The conductor 210_i may likewise be connected to a voltage potential, such as ground.

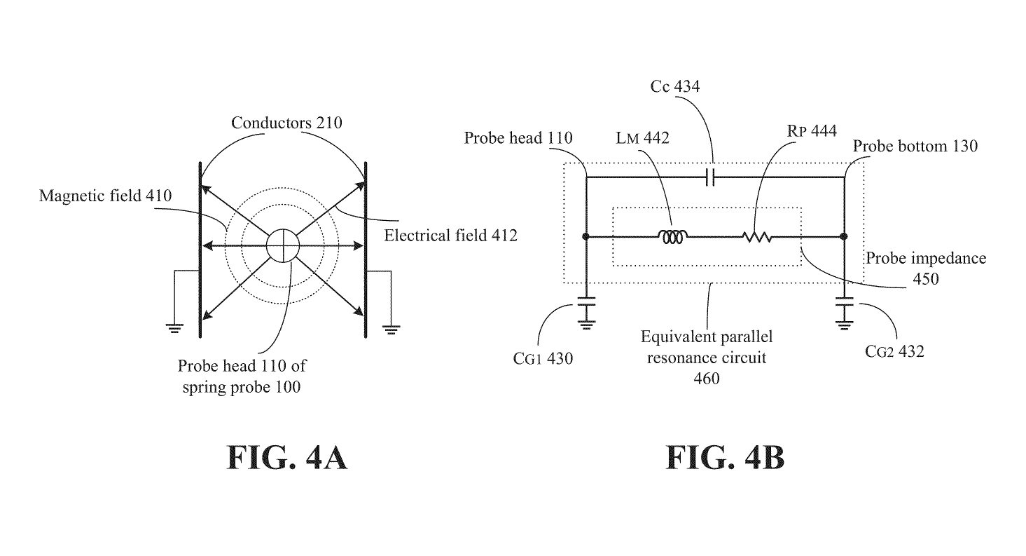

FIG. 4A is a diagram illustrating the electric and magnetic fields of a spring probe and the conductors. In the diagram, the first direction 150 is coming out of the page (i.e., the diagram looks down at the probe head 110). Magnetic field 410 emanates from the spring probe 100 in a circular direction around the spring probe 100. Electric field 412 is generated between the spring probe 100 and the conductors 210, which are connected to a voltage potential such as ground. The electric field 412 between the spring probe 100 and the conductors 210 is perpendicular to a magnetic field 410 of the probe.

FIG. 4B is a diagram illustrating the equivalent circuit of the probes and conductors. The probe impedance 450 of the spring probe 100 is represented by the inductor L_{M} 442 and the resistor R_{P} 444. Capacitances C_{C} 434, C_{G1} 430, and C_{G2} 432 are capacitances resulted from adding the conductors 210 (e.g., induced by the propagation of the electric field 412). The equivalent parallel resonance circuit 460 (including the inductor L_{M} 442, the resistor R_{P} 444, and the capacitance C_{C} 434) decreases reactance value of probe impedance 450 of the spring probe 100 and a self-resonance frequency, resulting in a lower effective inductance for the spring probe 100.

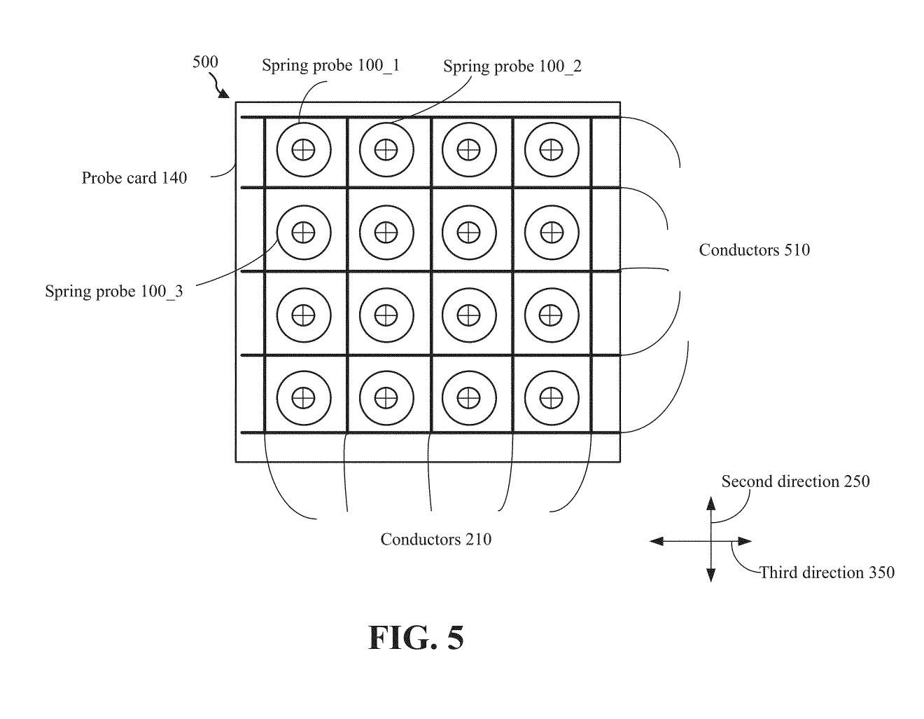

FIG. 5 is a diagram of a top view of another exemplary embodiment of a probe assembly. In this view, the first direction 150 is coming out of the page. The probe assembly 500 includes conductors 210, arranged in similar fashion as the probe assembly 200, and further includes conductors 510. The conductors 510 extend in the third direction 350, and may include a plurality of conductors parallel in the first direction 150. One of the conductors 510 may be connected with one of the conductors 210, and may include a metal wire. The conductors 510 may be connected to a voltage potential, such as ground. In one implementation, an electric field between a probe (e.g., spring probe 100_1) and the conductors 210 is perpendicular to the magnetic field of the probe. In one implementation, one of the conductors 510 passes between the spring probe 100_1 and the spring probe 100_3.

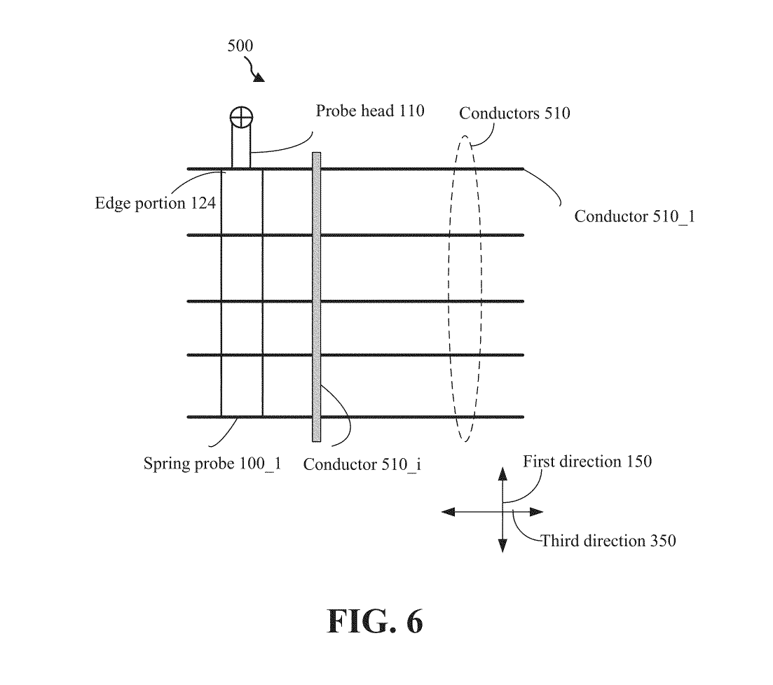

FIG. 6 is a diagram of a side view of another exemplary embodiment of a probe assembly. In this view, the second direction 250 would be coming out of the page. Only spring probe 100_1 is shown for clarity. The conductors 510 extend in the third direction 350 and include a plurality of conductors (e.g., conductor 510_1_{—} parallel in the first direction 150. The conductor 510_1 is generally aligned with the edge portion 124 of the spring probe 100_1. Optionally, the conductors 210 may include a conductor 510_i extending in the first direction 150. The conductor 510_i may include a metal wire, and may connect to the conductors 510. The conductor 510_i may likewise be connected to a voltage potential, such as ground.

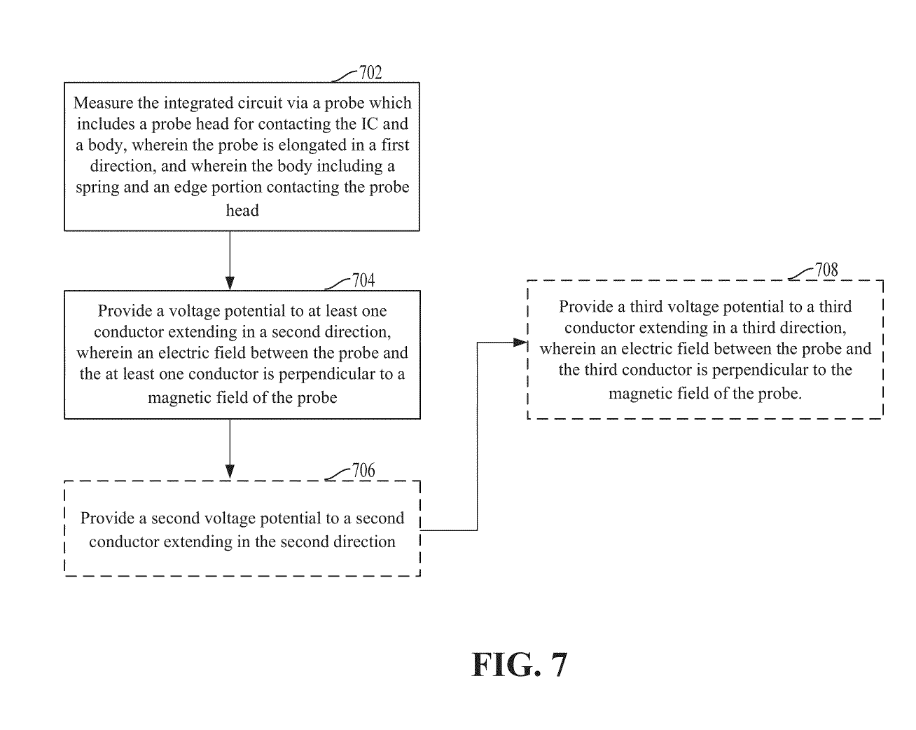

FIG. 7 is a flow chart for operating an exemplary embodiment of a probe assembly. Steps shown in dotted lines may be optional. The steps may be performed, e.g., by a tester connected to the probe assembly 500 for probing an integrated circuit on a wafer 190. At 702, the integrated circuit is measured via a probe which includes a probe head for contacting an integrated circuit and a body. The probe is elongated in a first direction. The body includes a spring and an edge portion contacting the probe head. See, e.g., the spring probe 100 illustrated in FIG. 1 and described in the accompanying text. The spring probe 100 contacts the integrated circuit on the wafer 190 for probing. The spring probe 100 is elongated on a first direction 150 and includes a probe head 110 for contacting the integrated circuit on the wafer 190 and a body 120. The body 120 includes a spring 122 and an edge portion 124 contacting the probe head 110.

At 704, a voltage potential is provided to at least one conductor extending in a second direction. An electric field between the probe and the at least one conductor is perpendicular to a magnetic field of the probe. See, e.g., FIG. 4A and the accompanying text. The voltage potential, ground, is provided conductors 210. The electric field 412 between the spring probe 100 and the conductors 210 is perpendicular to the magnetic field 410 of the spring probe 100.

At 706, a second voltage potential is provided to a second conductor extending in the second direction. See, e.g., FIG. 3B and the accompanying test. The conductors 210 include the conductor 210_1 and the conductor 210_2 extending the second direction 250. In one implementation, the voltage potential or ground is provided to the conductor 210_1. The second voltage potential may be the same as the voltage potential. In one implementation, the second voltage potential or ground is provided to the conductor 210_2. At 708, a third voltage potential is provided to a third conductor extending in a third direction. An electric field between the probe and the third conductor is perpendicular to the magnetic field of the probe. See, e.g., FIG. 5 and the accompanying text. The conductors 510 extending in the third direction 350. In one implementation, a third voltage potential or ground is provided to conductors 510. The electric field between the spring probe 100 and the conductors 510 is perpendicular to the magnetic field of spring probe 100, as described with FIG. 4A.

The specific order or hierarchy of blocks in the method of operation described above is provided merely as an example. Based upon design preferences, the specific order or hierarchy of blocks in the method of operation may be re-arranged, amended, and/or modified. The accompanying method claims include various limitations related to a method of operation, but the recited limitations are not meant to be limited in any way by the specific order or hierarchy unless expressly stated in the claims.

The previous description is provided to enable any person skilled in the art to fully understand the full scope of the disclosure. Modifications to the various exemplary embodiments disclosed herein will be readily apparent to those skilled in the art. Thus, the claims should not be limited to the various aspects of the disclosure described herein, but shall be accorded the full scope consistent with the language of claims. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112(f) unless the element is expressly recited using the phrase “means for” or, in the case of a method claim, the element is recited using the phrase “step for.”

What is claimed is:

1. A probe assembly for probing an integrated circuit, comprising:
a probe including a probe head for contacting the integrated circuit and a body, wherein the probe is elongated in a first direction, and wherein the body including a spring and an edge portion contacting the probe head; and
at least one conductor extending in a second direction and configured to connect to a voltage potential, wherein an electric field between the probe and the at least one conductor is perpendicular to a magnetic field of the probe.

2. The probe assembly of claim 1, wherein the voltage potential is ground.

3. The probe assembly of claim 1, wherein the at least one conductor is aligned with the edge portion of the body.

4. The probe assembly claim 1, wherein the probe head is configured to travel in the first direction for contacting the integrated circuit, and the at least one conductor is disposed at a position beyond the body in the first direction and allows the probe head to travel and contact the integrated circuit.

5. The probe assembly of claim 1, further comprising a second conductor extending in the second direction.

6. The probe assembly of claim 5, further comprising a third conductor connecting the at least one conductor and the second conductor.

7. The probe assembly of claim 5, wherein the at least one conductor and the second conductor are parallel in the first direction.

8. The probe assembly of claim 1, wherein the at least one conductor comprises a metal wire.

9. The probe assembly of claim 1, further comprising a second conductor extending in a third direction and configured to connect to the voltage potential, wherein an electric field between the probe and the second conductor is perpendicular to the magnetic field of the probe.

10. A probe assembly for probing an integrated circuit, comprising:
a first probe and second probe, wherein each of the first probe and the second probe is elongated in a first direction and is configured to contact the integrated circuit;
at least one conductor extending in a second direction between the first probe and the second probe, wherein the at least one conductor is connected to a voltage potential.

11. The probe assembly of claim 10, further comprising a second conductor between the first probe and the second probe.

12. The probe assembly of claim 11, wherein the second conductor extends in the second direction and is parallel to the at least one conductor in the first direction.

13. The probe assembly of claim 10, further comprises
a third probe; and
a third conductor extending in a third direction between the first probe and the third probe, wherein the third conductor is connected to the voltage potential.

14. A method for operating a probe assembly for probing an integrated circuit, comprising:
measuring the integrated circuit via a probe which includes a probe head for contacting the integrated circuit and a body, wherein the probe is elongated in a first direction, and wherein the body including a spring and an edge portion contacting the probe head; and
providing a voltage potential to at least one conductor extending in a second direction, wherein an electric field between the probe and the at least one conductor is perpendicular to a magnetic field of the probe.

15. The method of claim 14, wherein the voltage potential is ground.

16. The method of claim 14, wherein the at least one conductor is aligned with the edge portion of the body.

17. The method of claim 14, wherein the probe head is configured to travel in the first direction for contacting the integrated circuit, and the at least one conductor is disposed at a position beyond the body in the first direction and allows the probe head to travel and contact the integrated circuit.

18. The method of claim 14, further comprising providing a second voltage potential to a second conductor extending in the second direction.

19. The method of claim 18, further comprising providing a third voltage potential to a third conductor extending in a third direction, wherein an electric field between the probe and the third conductor is perpendicular to the magnetic field of the probe.

20. The method of claim 19, wherein the voltage potential, the second voltage potential, and the third voltage potential are ground.
